(19) United States
(12) Patent Application Publication
(10) Pub. No.: US 2011/0234239 A1
(43) Pub. Date: Sep. 29, 2011

(54) Two-Port De-Embedding Using Time Domain Substitution

(75) Inventor: Donald W. Metzger, Colorado Springs, CO (US)

(73) Assignee: Constant Wave, Inc., Colorado Springs, CO (US)

(21) Appl. No.: 13/048,563

(22) Filed: Mar. 15, 2011

Related U.S. Application Data
(60) Provisional application No. 61/316,731, filed on Mar. 23, 2010.
(60) Provisional application No. 61/334,250, filed on May 13, 2010.

(51) Int. Cl. G01R 27/28

(52) U.S. Cl. 324/617

(57) ABSTRACT

A method is provided for de-embedding the S-parameter response of an electrical DUT embedded in an electrical network. The method comprises making first and second sets of S-parameter measurements in the frequency domain at a port or measurement reference plane to the network containing the DUT. For the second measurement, a known impedance condition is created at the embedded location of the DUT. The first and second sets of measurements are transformed to the time domain, and then gated to select portions of the time-domain-transformed responses that correspond to paths that include the DUT and known impedance condition, respectively. The gated time domain responses are then transformed back into the frequency domain, yielding first and second sets of selected S-parameter measurement responses. Reflection S-parameters for the DUT are then determined as a function of the first and second sets of selected S-parameter measurement responses and the known impedance condition.

### RELATED APPLICATIONS

This application claims priority to and herein incorporates by reference U.S. Provisional Patent Application No. 61/334,250, filed on May 24, 2010, entitled “Two Port Device De-Embedding for Network Analyzers Using Time Domain Processing” and U.S. Provisional Patent Application No. 61/316,731, filed on Mar. 23, 2010, entitled “One Port Device De-embedding for Network Analyzers Using Time Domain Processing.”

### FIELD OF THE INVENTION

This invention relates generally to the use of vector network analyzers (VNAs), and more particularly, to de-embedding the response of the device under test (DUT) from the measurements that include the intervening physical components between the VNA and the DUT.

### BACKGROUND

Vector Network Analyzers (VNAs) are radio frequency (RF) measurement systems used to determine the scattering parameters (commonly referred to as “S-parameters”) of a device under test (DUT). A VNA generates a single frequency, continuous wave (CW) stimulus signal. This signal is sent through cables to a DUT. The stimulus and the DUT response signals are measured by the VNA. A new stimulus signal is then generated at a different frequency. The response of the DUT is similarly determined for this new frequency. This process continues over a range of frequencies. The result is the response of the DUT at multiple frequencies. These results are termed frequency domain responses, because the measured data is a function of the stimulus frequency.

The foregoing measured responses, however, are distorted by the intrinsic electrical characteristics (e.g., capacitance, inductance, resistance) of the physical components (e.g., VNA cables and printed circuit board) between the VNA and the DUT. Errors caused by the VNA cables can be removed from these measured signals through a relatively easy process called correction. But, as explained below, the conventional process for removing errors caused by other elements, such as an intervening printed circuit board, is much more tedious and difficult. Often, calibration kits are not available for such elements. Consequently, customers often fail to perform the needed corrections.

A common VNA measurement problem involves making two port, S-parameter measurements of a device where there is intervening circuitry between the measurement ports and the device. A signal flow graph of this measurement is shown in FIG. 3. It is desired to measure the four transfer functions D11, D12, D21 and D22, which are the four S-parameters of the DUT. However, there are intervening physical elements between the measurement points at a₁, b₁, a₂ and b₂ and the device at D. Those intervening elements are modeled as L, a two port network, P1 and P2, transmission lines, and R, a two port network. This is a very general model which can fit many actual measurement scenarios.

The S-parameters for D are desired, but the intervening circuitry introduces complexity into the equation which involves all of the terms in the model. The challenge is how to extract D from the measured S-parameters of the total system. In the language of VNAs, the problem of extracting D from the measured S-parameters is known as de-embedding. Where the measurement involves two ports, the problem is known more fully as two-port de-embedding.

One current approach to this problem involves the insertion of various known devices (calibration standards) at the location D. Measurements with these known standards can be used to characterize the L and R two-port terms and the P1 and P2 propagation characteristics of the transmission lines. Once the L, R, P1 and P2 terms have been determined, they can used to de-embed the D S-parameters from the measured S-parameters of the system. This process is called calibration. This approach requires that multiple calibration standards be inserted and measured, a time consuming process. In addition, the creation of those multiple standards can be a difficult task.

### SUMMARY

A novel method is provided for de-embedding the S-parameter response of an electrical DUT embedded in a two-port electrical network. The method relies on a combination of key insights.

The first insight is that a signal fed by a VNA to a DUT produces multiple reflections, each corresponding to a different propagation path for the signal, spaced apart in time. These reflections can be isolated by transforming the S-parameter response to the time domain, applying a gate to select a portion of the response corresponding to a particular path, and transforming the gated response back into the frequency domain.

The second insight is that no matter which individual path is chosen, the path equations characterizing the signals through that path will always be defined as a string of products, which are readily and easily solved.

The third insight is that by substituting a single known impedance condition at the location of the DUT, and making an otherwise identical measurement, inverse transformation, gating, and forward transformation, the S-parameter response of the DUT can be solved as a function of the measurements and the known impedance condition.

Accordingly, the method comprises making first and second sets of S-parameter measurements in the frequency domain at ports to the network containing the DUT. For the second set of measurements, a known impedance condition is created at the embedded location of the DUT. The first and second sets of measurements are transformed to the time domain, and then gated to select portions of the time-domain-transformed responses that correspond to paths that include the DUT and known impedance condition, respectively. The gated time domain responses are then transformed back into the frequency domain, yielding first and second sets of selected S-parameter measurement responses. Reflection S-parameters for the DUT are then determined as a function of the first and second sets of selected S-parameter measurement responses and the known impedance condition.

These and other aspects, features, and advantages of the present invention will be readily apparent to those skilled in the art from the following detailed description taken in conjunction with the annexed sheets of drawings, which illustrate the invention. The invention, however, is not limited by systems with any particular combination of the described features, aspects, and advantages, except and to the extent specifically so limited by the claims.

### BRIEF DESCRIPTION OF THE DRAWINGS

FIG. 1 illustrates one embodiment of a common test configuration for a device under test.

FIG. 2 illustrates one embodiment of an electrical network model for a device under test.

FIG. 3 illustrates one embodiment of a signal flow graph for modeling the measurement of a two-port device.

FIG. 4 illustrates a first impulse response through the signal flow graph of FIG. 3.

FIG. 5 illustrates a second impulse response through the signal flow graph of FIG. 3.

FIG. 6 illustrates the substitution of a known impedance condition or device K at the location of the DUT in the signal flow graph of FIG. 3.

FIG. 7 illustrates a transmission path through the signal flow graph of FIG. 3.

FIG. 8 is a flow chart of one embodiment of a method of de-embedding the scattering response of an electrical device under test embedded in a two-port electrical network.

### DETAILED DESCRIPTION

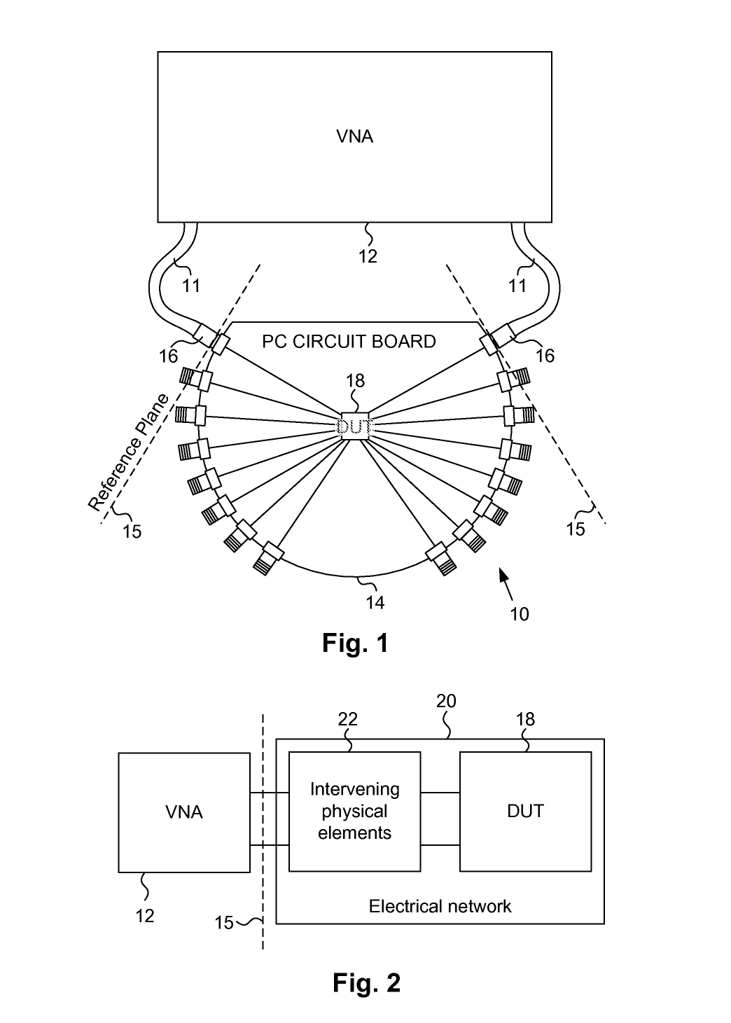

FIG. 1 illustrates one embodiment of a common test configuration 10 for a device under test (DUT). The DUT 18 is embedded in a printed circuit board 14 with radially-extending coaxial cable connectors for transferring signals to and from each of the pins of the DUT 18. A vector network analyzer (VNA) 12 is connected, via coaxial cables, to two of the coaxial inputs 16 of the printed circuit board 14.

Typically, the VNA will be calibrated at the cable ends, to correct scattering parameter measurements for errors introduced by the coaxial cable 11 and the VNA 12. But as illustrated in FIGS. 1 and 2, there is frequently additional circuitry (e.g., wire) between the measurement point—also referred to as the reference plane 15—and the DUT 18.

FIG. 2 illustrates one embodiment of an electrical network model that is applicable to any test configuration in which the measurement reference plane 15 is remote from the DUT 18. The test configuration is modeled as a VNA 12 connected to an electrical network 20 containing the DUT 18. Signals transmitted between the reference plane 15 and the DUT 18 pass through intervening physical elements 22 with inherent electrical properties (e.g., capacitance, inductance, resistance). The challenge is to de-embed the scattering response of the DUT from the measured scattering response at the reference plane.

The present invention approaches de-embedding through a novel process referred to herein as time domain substitution. A key insight of this novel process is the recognition that a signal fed by a VNA to a DUT produces multiple reflections, spaced apart in time. Each reflection corresponds to a different propagation path for the signal. The reflections are spaced apart in time because propagation through different paths takes different amounts of time.

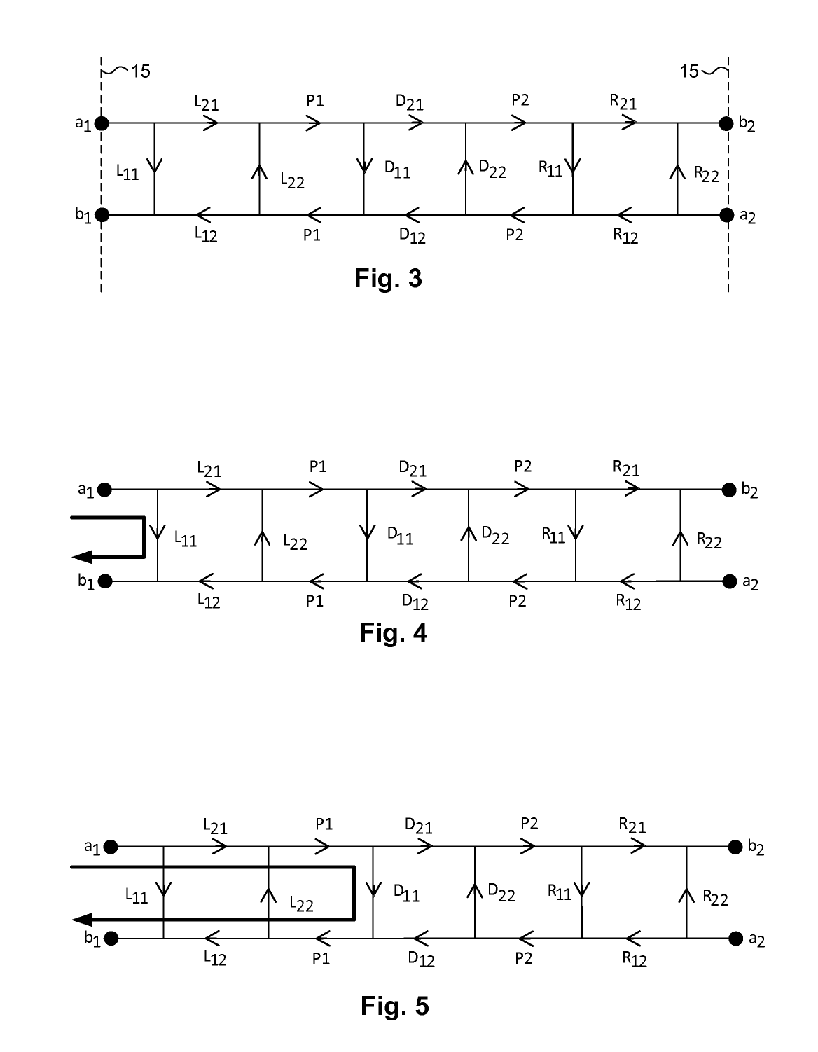

FIG. 3 is a general signal flow model of the intervening physical elements between the measurement points at a1, b1, a2 and b2 (known as the “reference plane”) and the DUT location at D. Those intervening elements are modeled as L, a two port network, P1 and P2, transmission lines, and R, a two port network. This general model fits many actual measurement scenarios.

FIG. 4 illustrates that the first impulse response in time arises from the L₁₁ path. The equation for S11 of the path shown in FIG. 4 is:

$${S}_{11} = \frac{{b}_{1}}{{a}_{1}} = {L}_{11} \qquad ( 1 )$$

This first impulse response does not include the device D and, while it characterizes one aspect of the intervening circuitry, does not help with the measurement of the device.

FIG. 5 illustrates that the second impulse response in time arises from a path which includes the device D. The equation of S₁₁ for the path shown in FIG. 5 is:

$${S}_{11} = \frac{{b}_{1}}{{a}_{1}} = {L}_{12} {L}_{21} P {1}^{2} {D}_{11} \qquad ( 2 )$$

Isolating the S-parameter response to the second impulse response involves a series of steps. First, the VNA tests the DUT with several regularly spaced frequencies in order to facilitate a transform to the time domain.

Second, the frequency domain responses measured by the VNA are transformed, using inverse Fourier transforms, into time domain responses. This step, in the context of VNAs, is known as “Time Domain Processing.” The form of the inverse Fourier transform used can be a Discrete Fourier Transform, a Fast Fourier Transform or a Chirp-Z Transform. Various shapes of windowing functions can be applied to the frequency domain data before it is transformed, in order to control certain behaviors of the resulting time domain responses. These behaviors include sidelobe level, sidelobe roll-off rate and time domain resolution.

Third, the part of the time domain response corresponding to the propagation path that includes D is gated and forward transformed back to the frequency domain. This processing step is known as “Frequency Gated By Time,” and yields a frequency domain response—for example, the S₁₁ of equation (2)—that represents only the selected part of the time domain response. Various methods for performing this forward Fourier transform may be used.

The frequency domain responses measured by a VNA are more generally known as transfer functions. The time domain responses computed from these transfer functions are more generally known as impulse response functions. The frequency gated by time responses computed by selecting a portion of the impulse response functions and transforming back to the frequency domain are, again, transfer functions. However, these transfer functions are based on only a portion of the total impulse response of the DUT. By careful selection of which parts of the impulse response are used in the computation of the transfer function, the transfer function for different propagation paths within the device under test can be determined.

The application of time domain processing as set forth above selects one path from the network and created a simple mathematical equivalent for the measurement (see equation (2)). The relative simplicity of this equation facilitates a straightforward determination of D11, as described below.

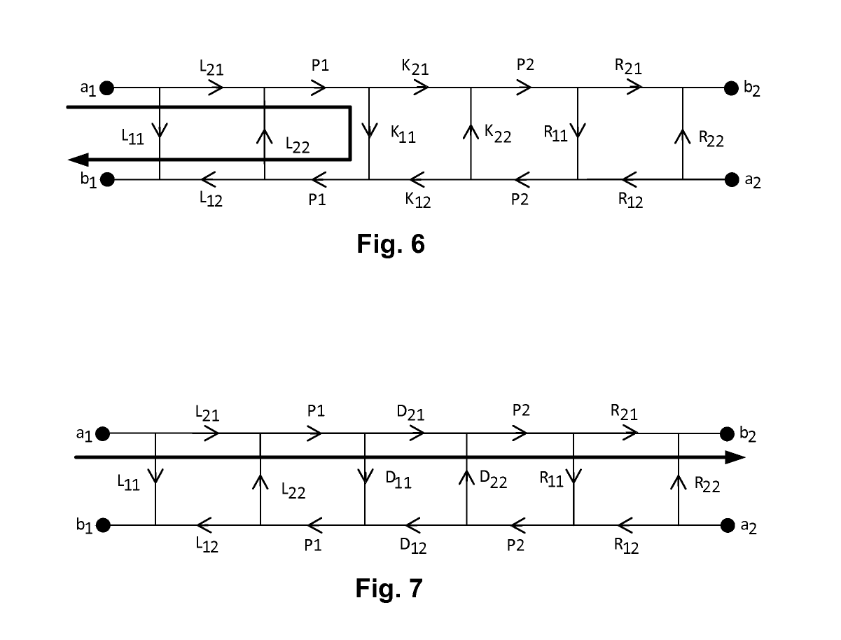

Another key aspect of the present invention is to substitute a known device K for D, as shown in FIG. 6, and make another measurement. Referring to the known value of K on the port 1 side as K₁₁, the equation of S₁₁ for the path shown in FIG. 6 is:

$${S}_{11} = \frac{{b}_{1}}{{a}_{1}} = {L}_{12} {L}_{21} P {1}^{2} {K}_{11} \qquad ( 3 )$$

In order to avoid confusion, the S₁₁ measured when D is in place will hereinafter be referred to as M1. Also, the S₁₁ measured when K₁₁ is in place will hereinafter be referred to as M2. Thus, equations 2 and 3 can be rewritten as equations 4 and 5, respectively:

M1=L₁₂L₂₁P1²D₁₁ (4)

M2=L₁₂L₂₁P1²K₁₁ (5)

Dividing equation 4 by equation 5 yields

$$\frac{M 1}{M 2} = \frac{{D}_{11}}{{K}_{11}} \qquad ( 6 )$$

Notably, the parts in common for the two measurements cancel. Equation 6 now contains two values, M1 and M2, which are both determined by measurements. The value K₁₁ is assumed to be known. Therefore, equation 7 can be solved for D₁₁ as

$${D}_{11} = \frac{M 1}{M 2} {K}_{11} \qquad ( 7 )$$

The value for D₁₁ has been determined by two measurements, one with device D in place, and one with a single known device K in place. Because this method involves time domain processing and the substitution of K for D, this method is herein given the name of “Time Domain Substitution.”

The value of D₂₂ can be found by a similar approach involving S₂₂ measurements. First, S₂₂ is measured with the device D in place. Using time domain processing the second reflection in time is isolated. This value will be referred to herein as M3. Next, the device D is replaced with a known device K with value K₂₂. S₂₂ is measured and, using time domain processing, the second reflection in time is isolated. This value will be referred to herein as M4. Therefore, we have the following equations for M3 and M4:

M3=R₁₂R₂₁P2²D₂₂ (8)

M4=R₁₂R₂₁P2²R₂₂ (9)

The D₂₂ can then be found as:

$${D}_{22} = \frac{M 3}{M 4} {K}_{22} \qquad ( 10 )$$

Accordingly, the value for D₂₂ has been determined by two measurements, one with device D in place, and one with a known device K in place. The measurement M3 can be done at the same time, or different times, as measurement M1. Likewise, the measurement M4 could be done at the same time, or different times, as measurement M2.

Time domain substitution may also be used to determine values for D₁₂ and D₂₁. FIG. 7 illustrates the response for D₂₁ which occurs first in time. The equation of S₂₁ for the path shown in FIG. 7 is:

$${S}_{21} = \frac{{b}_{2}}{{a}_{1}} = {L}_{21} {R}_{21} P 1 P 2 {D}_{21} \qquad ( 11 )$$

Referring to the measured value of S₂₁ which is made with the DUT D in place as M5, then:

M5=L₂₁R₂₁P1P2D₂₁ (12)

Now, device D is replaced with a known device K with value K₂₁. Referring to the measured value of S₂₁ which is made with K substituted for D as M6, then:

M6=L₂₁R₂₁P1P2K₂₁ (13)

The D₂₁ can then be found as:

$${D}_{21} = \frac{M 5}{M 6} {K}_{21} \qquad ( 14 )$$

From FIG. 7, it will be evident that the equation S₁₂ is similar to the equation for S₂₁:

$${S}_{12} = \frac{{b}_{1}}{{a}_{2}} = {L}_{12} {R}_{12} P 1 P 2 {D}_{12} \qquad ( 15 )$$

Referring to the measured value of S₁₂ which is made with the DUT D in place as M7, then:

M7=L₁₂R₂₁P1P2D₁₂ (16)

Now, device D is replaced with a known device K with value K₁₂. Referring to the measured value of S₁₂ which is made with K substituted for D as M8, then:

M8=L₁₂R₂₁P1P2K₁₂ (17)

The D₁₂ can then be found as:

$${D}_{12} = \frac{M 7}{M 8} {K}_{12} \qquad ( 18 )$$

If the L and R two port networks represent reciprocal networks, which is the usual case for passive networks, then L₁₂=L₂₁ and R₁₂=R₂₁. Using this assumption, along with equations 5 and 9, equations 12 and 16 can be rearranged to yield:

$$\begin{matrix}{D}_{21} = M 5 \sqrt{\frac{{K}_{11} {K}_{22}}{M 2 M 4}} & ( 19 ) \\ {D}_{12} = M 7 \sqrt{\frac{{K}_{11} {K}_{22}}{M 2 M 4}} & ( 20 )\end{matrix}$$

Accordingly, D₂₁ and D₁₂ can be determined from measurements of the first pulse which arrives at the opposite port for the S₂₁ or S₁₂ parameter, and from the previous measured values M1, M2 and the known one port standards K₁₁ and K₂₂. In equations 19 and 20, the square root function has two roots with equal magnitudes, but phases which differ by 180 degrees. The magnitudes of D₂₁ and D₁₂ are unaffected by the choice of root. The phase of D₂₁ or D₁₂ can be chosen by which root yields a phase of D₂₁ or D₁₂ which is appropriate to an approximately known electrical length for D₂₁ or D₁₂.

In many practical situations, the unknown device D can be replaced with a known device K simply by short circuiting the input and output of the device D. Thus, one suitable known device K is a short circuit of the input and output of device D. Another possibility for the known device K is an open circuit.

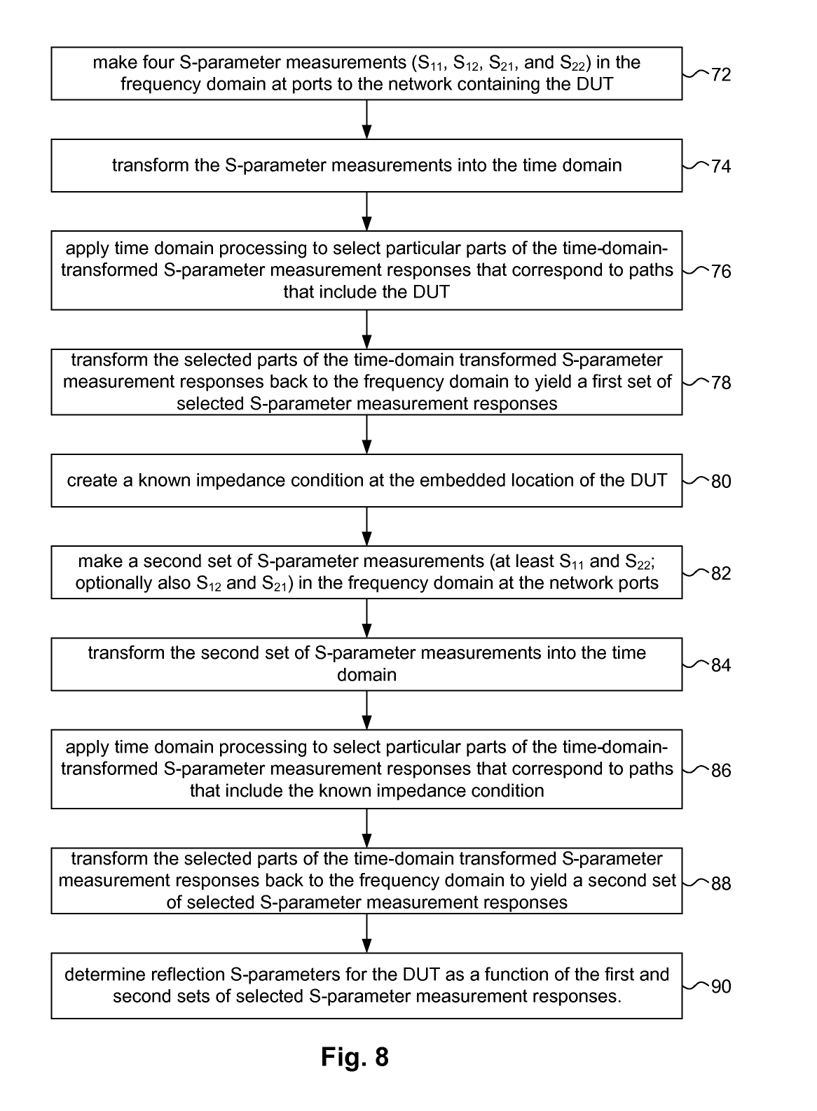

FIG. 8 is a flow chart of one embodiment of a method of de-embedding the S-parameter response of an electrical DUT embedded in a two-port electrical network. In function block 72, a VNA is used to perform a first set of S-parameter measurements S₁₁, S₁₂, S₂₁, and S₂₂, in the frequency domain, at ports to the network containing the DUT. In function block 74, each of the first set of S-parameter measurements is transformed into the time domain using a DFT, FFT, or Chirp-Z transform. In function block 76, time domain processing is applied to select particular parts of the time-domain-transformed S-parameter measurement responses that correspond to paths that include the DUT. The impulse response representing the DUT in the time domain trace is selected as in normal Frequency Gated by Time processing. For S₁₁ and S₂₂ processing, this impulse response could be the first impulse, or a subsequent one, depending on the actual topology of the network being measured. For S₂₁ and S₁₂, the impulse response will likely be the first one in time. In function block 78, the selected parts of the time-domain transformed first S-parameter measurement responses are transformed back to the frequency domain, using a suitable transform such as DFT, FFT, or Chirp-Z, to yield a first set of selected or isolated S-parameter measurement responses. These frequency domain traces are denoted as follows: M1 for the result of processing applied to S₁₁; M3 for the result of processing applied to S₂₂; M5 for the result of processing applied to S₂₁; and M7 for the result of processing applied to S₁₂.

In function block 80, a known impedance condition is created at the embedded location of the DUT. This may be done by applying a short or open circuit at the location of the DUT. In function block 82, the VNA is used to make a second set of S-parameter measurements, in the frequency domain, at the same network ports referenced in function block 72. The second set of measurements will typically consist of S₁₁ and S₂₂ if the L and R two port networks represent reciprocal networks. Otherwise, the second set of measurements will typically consist of S₁₁, S₂₂, S₂₁ and S₁₂.

In function block 84, each of the second set of S-parameter measurements is transformed into the time domain using a DFT, FFT, or Chirp-Z transform. In function block 86, time domain processing is applied to select particular parts of the time-domain-transformed second S-parameter measurement responses that correspond to paths that include the known impedance condition. In function block 88, the selected parts of the time-domain transformed S-parameter measurement responses are transformed back to the frequency domain, again using a suitable transform such as DFT, FFT, or Chirp-Z, to yield a second set of selected or isolated S-parameter measurement responses. These frequency domain traces are denoted as follows: M2 for the result of processing applied to S₁₁; M4 for the result of processing applied to S₂₂; M6 for the result of processing applied to S₂₁; and M8 for the result of processing applied to S₁₂.

In function block 90, reflection S-parameters for the DUT, denoted as D, are determined as a function of the first and second sets of selected S-parameter measurement responses. Equations 7, 10, 14, 18, 19 and 20 are representative of such functions.

It will be understood that several variations can be applied to the process without departing from the spirit and scope of the invention. For example, the processing used to generate responses in the time domain, select a part of the time domain and transform back to the frequency domain, may be a Frequency Gated By Time processing, such as that available in the time domain processing of a VNA. Alternatively, this processing may be based on spectrographic processing. The known impedance condition or known device could be a short or open circuit. The DUT could be two one port devices or a single two port device. The S₁₁ and S₂₂ measurements of the DUT could be performed as one port measurements or as a two port measurement of all four S-parameters. The VNA making measurements could be either uncalibrated or calibrated using a previous calibration process.

Although the foregoing specific details describe various embodiments of this invention, persons reasonably skilled in the art will recognize that various changes may be made in the details of the method and apparatus of this invention without departing from the spirit and scope of the invention as defined in the appended claims. Therefore, it should be understood that, unless otherwise specified, this invention is not to be limited to the specific details shown and described herein.

I claim:

1. A method of de-embedding the scattering parameter (S-parameter) response of an electrical device under test (DUT) embedded in a two-port electrical network, the method comprising:
making a first set of S-parameter measurements in the frequency domain at ports to the network containing the DUT;
transforming the first set of S-parameter measurements into the time domain;
applying time domain processing to select particular parts of the time-domain transforms of the first set of S-parameter measurements that correspond to paths that include the DUT;
transforming the selected parts of the time-domain transforms of the first set of S-parameter measurements back to the frequency domain to yield a first set of selected S-parameter measurement responses;
creating a known impedance condition at the embedded location of the DUT;
making a second set of S-parameter measurements at the port to the network having a known impedance condition at the location of the DUT;
transforming the second set of S-parameter measurements into the time domain;
applying time domain processing to select particular parts of the time-domain transforms of the second set of S-parameter measurements that correspond to paths that include the known impedance condition;
transforming the selected parts of the time-domain transforms of the second set of S-parameter measurements back to the frequency domain to yield a second set of selected S-parameter measurement responses; and
determining reflection and transmission S-parameters for the DUT as a function of the first and second sets of selected S-parameter measurement responses.

2. The method of claim 1, wherein the first set of S-parameter measurements comprise S₁₁, S₂₂, S₂₁, and S₁₂.

3. The method of claim 2, wherein:
S₁₁ is a reflection measurement at a first port to the two-port electrical network;
S₂₂ is a reflection measurement at a second port to the two-port electrical network; and
S₂₁ and S₁₂ are transmission measurements between the first and second ports of the two-port electrical network.

4. The method of claim 3, wherein the second set of S-parameter measurements consist essentially only of two measurements.

5. The method of claim 4, wherein the two measurements of the second set of S-parameter measurements are S₁₁ and S₂₂ measurements taken with the known impedance condition at the embedded location of the DUT.

6. The method of claim 5, wherein in the second set of S-parameter measurements:
S₁₁ is a reflection measurement at a first port to the two-port electrical network; and
S₂₂ is a reflection measurement at a second port to the two-port electrical network.

7. The method of claim 3, wherein the second set of S-parameter measurements comprise four measurements.

8. The method of claim 7, wherein the four measurements of the second set of S-parameter measurements are S₁₁, S₂₂, S₂₁ and S₁₂ measurements taken with the known impedance condition at the embedded location of the DUT.

9. The method of claim 8, wherein in the second set of S-parameter measurements:
S₁₁ is a reflection measurement at a first port to the two-port electrical network;
S₂₂ is a reflection measurement at a second port to the two-port electrical network; and
S₂₁ and S₁₂ are transmission measurements between the first and second ports of the two-port electrical network.

10. The method of claim 1, wherein the reflection and transmission S-parameters determined for the DUT include D₁₁, D₂₂, D₂₁, and D₁₂, which are determined by the following relationships:
$${D}_{11} = {K}_{11} * M 1 / M 2 ;$$
$${D}_{22} = {K}_{22} * M 3 / M 4 ;$$
$${D}_{21} = M 5 \sqrt{\frac{{K}_{11} {K}_{22}}{M 2 M 4}} ; and$$
$${D}_{12} = M 7 \sqrt{\frac{{K}_{11} {K}_{22}}{M 2 M 4}} ;$$
wherein K₁₁ and K₂₂ are known one-port standards, and wherein M1, M3, M5, and M7 denote the first set of selected S-parameter measurement responses and wherein M2 and M4 denote the second set of selected S-parameter measurement responses.

11. The method of claim 1, wherein the known impedance condition is an open circuit.

12. The method of claim 1, wherein the known impedance condition is a short.
